(19) United States
(12) Patent Application Publication
(10) Pub. No.: US 2022/0359342 A1
(43) Pub. Date: Nov. 10, 2022

(54) SECURING POWER SEMICONDUCTOR COMPONENTS TO CURVED SURFACES

(71) Applicant: Rolls-Royce Deutschland Ltd & Co KG, Blankenfelde-Mahlow (DE)

(72) Inventors: Markus Lasch, München (DE); Claus Müller, Wolfratshausen (DE); Oliver Raab, Ortenburg (DE); Stefan Stegmeier, München (DE); Uwe Waltrich, Erlangen (DE)

(21) Appl. No.: 17/621,832

(22) PCT Filed: May 29, 2020
(86) PCT No.: PCT/EP2020/065052

§ 371 Date: Dec. 22, 2021

(30) Foreign Application Priority Data
Jun. 24, 2019 (DE) 10 2019 209 069.9

(51) Int. Cl. H01L 23/40; H01L 23/049; H01L 21/48; H05K 3/00

(52) U.S. Cl. CPC H01L 23/4006; H01L 23/4093; H01L 23/049; H01L 21/4882; H05K 3/0061

(57) ABSTRACT

The disclosure relates to an arrangement with a power module including power semiconductor components. The arrangement further includes a component having a curved surface. The power module is arranged on the curved surface of the component and is non-positively detachably connected to the component. The disclosure also relates to a power converter with the arrangement and to a vehicle with a power converter.

The present patent document is a § 371 nationalization of PCT Application Serial No. PCT/EP2020/065052, filed May 29, 2020, designating the United States, which is hereby incorporated by reference, and this patent document also claims the benefit of German Patent Application No. 10 2019 209 069.9, filed Jun. 24, 2019, which is also hereby incorporated by reference.

### TECHNICAL FIELD

The disclosure relates to an arrangement including a power module, which has power semiconductor components, and a component (e.g., a heat sink). A power converter including an arrangement of this kind and a vehicle including a power converter are also provided.

### BACKGROUND

It is known to connect power modules including power semiconductor components as a flat assembly to a planar cooler (e.g., heat sink). However, if the cooler is in a bent arrangement (for example, as a round cooler) or if a pre-existing structural component is intended to be used as a cooling surface, great effort is required to connect the power electronics. For example, milling operations have to be performed in the cooler or relatively large quantities of thermally conductive paste have to be introduced as a compensating medium or existing thin-walled structural components have to be made thicker. The latter also has a negative effect on the system weight.

If this is not possible or if the space available is limited (e.g., in the case of special superstructures in the motor area), it is advantageous if the power module (e.g., including substrate and base plate) may be installed in a bent state. In addition to the space available, more efficient cooling may also take place here, this being directly associated with the service life or performance of the semiconductor chips and therefore of the entire power module.

Power electronics variants that are concerned with a three-dimensional arrangement of the circuit or the modules are known. However, they all share the common feature that the power module is connected in a planar manner, e.g., not bent. In addition to these variants, there are other possible ways of achieving a three-dimensional arrangement.

For example, flexible circuit boards have become increasingly established as circuit carriers in recent years since compact and complex superstructures may be realized. The circuit carrier may include polyimide with a thickness in a range of 25 and 100 micrometers (μm) and is connected on one or both sides to rolled copper with a thickness in a range of 18 and 70 μm by an adhesive (e.g., acrylic) or directly by heat compression. Owing to the low thickness and the high crack resistance of polyimide, the circuit board may therefore be connected to curved surfaces, e.g., of a bent cooler. One disadvantage, however, is the limited copper conductor track thickness which is only suitable to a limited extent for power electronics applications.

In another example, in a mechatronic integrated device (MID), a catalyst-filled polymer is melted at the later conductor track points by a laser (e.g., CO₂ laser) and the concentration of the catalyst, (e.g., palladium), is increased. A subsequent electroless plating act may grow at the catalyst and thus reinforce the conductor tracks. The polymer injection molding process results in a high degree of freedom in terms of geometries, such as bent surfaces for example. However, this method has the disadvantage that there is slow growth of the conductor tracks and thus only small layer thicknesses may be produced.

### SUMMARY

The object of the disclosure is to provide a solution which allows power semiconductor components to be reliably secured to curved surfaces, in particular of coolers.

The scope of the present disclosure is defined solely by the appended claims and is not affected to any degree by the statements within this summary. The present embodiments may obviate one or more of the drawbacks or limitations in the related art.

One aspect of the disclosure involves specifying a novel solution for realizing bent power electronics which firstly may be constructed in a space-saving manner and secondly provides a high level of heat dissipation.

The disclosure recites an arrangement including at least one power module, which has power semiconductor components, and including a component, (e.g., a heat sink), wherein the component has a curved surface, and the power module is arranged on the surface and is releasably connected to the component in a non-positive manner.

In one development, the power module may have a casing with internal dies, wherein the dies are configured to press onto the power semiconductors or onto a circuit carrier of the power module in the direction of the surface of the component.

In a further refinement, the power semiconductor components may be arranged on the circuit carrier.

In a further embodiment, the casing may be fixed on the component in a non-positive manner by screws.

In a further refinement, the casing may be fixed on the component in a non-positive manner using a shroud loop fixed by screws.

In a further refinement, the casing may be fixed on the component in a non-positive manner using clamps.

In a further refinement, a plurality of power modules with casings may be fixed on the component in a non-positive manner using a single shroud loop or a shrink-fit tube.

In a further development, the component may be cylindrical and the shroud loop may wrap around the component, wherein the two ends of the shroud loop are fixed in an anchor point on the component.

In a further refinement, an elastic first thermally conductive material may be arranged between the component and the power module.

In a further embodiment, the casing may be filled with an elastic second thermally conductive material.

The disclosure also recites a power converter, in particular a converter, including the arrangement disclosed herein.

A power converter which uses an AC voltage or DC voltage to produce an AC voltage, the frequency and amplitude of which are varied, is referred to as a converter, also called an inverter. Converters may be configured as AC/DC-DC/AC converters or DC/AC converters, wherein an AC output voltage is generated from an AC input voltage or a DC input voltage via a DC link and clocked semiconductors.

The disclosure also recites a vehicle, (e.g., an aircraft), including a power converter as disclosed herein for an electric or hybrid-electric drive.

A vehicle is understood to mean any type of locomotion or transport apparatus or system, whether manned or unmanned. An aircraft is a flying vehicle.

In one development, the aircraft has an electric motor supplied with electrical energy by the converter and a propeller that may be set in rotation by the electric motor.

Further special features and advantages of the disclosure become clear from the following explanations of a plurality of exemplary embodiments with reference to schematic drawings.

### BRIEF DESCRIPTION OF THE DRAWINGS

In the drawings:

FIG. 1 shows a sectional view of an arrangement of a first exemplary embodiment.

FIG. 2 shows a sectional view of an arrangement of a second exemplary embodiment.

FIG. 3 shows a sectional view of an arrangement of a third exemplary embodiment.

FIG. 4 shows a sectional view of an arrangement of a fourth exemplary embodiment.

FIG. 5 shows a block diagram of a power converter including a power module according to an embodiment.

FIG. 6 shows an example of an aircraft including an electrical thrust-generating unit.

### DETAILED DESCRIPTION

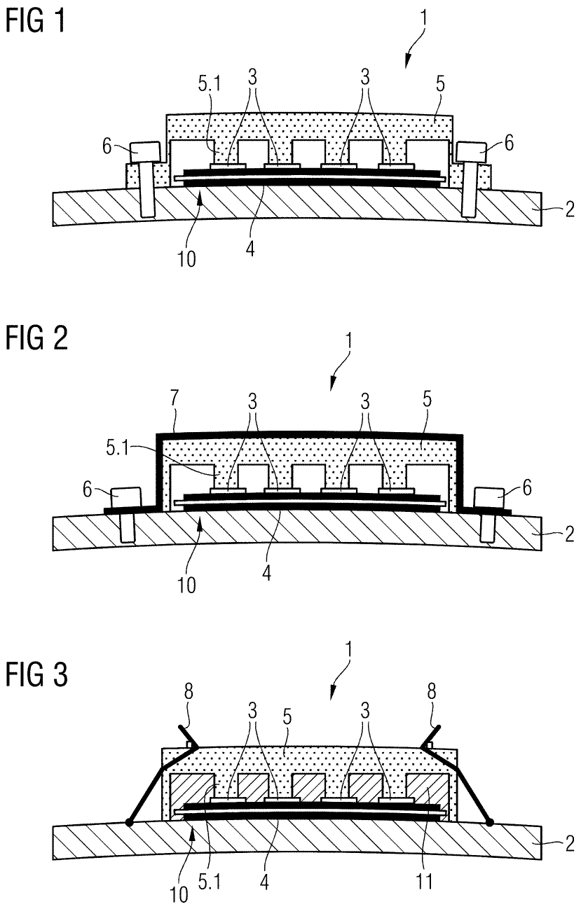

FIG. 1 to FIG. 4 show sectional views of exemplary embodiments of how the power-electronics circuit (e.g., power module 1) is brought into contact with a one-dimensionally curved component 2, e.g., a heat sink. A circuit carrier 4 on which the power semiconductor components 3 are arranged is located on the bottom side of the power module 1. In this case, the power module 1 is pressed permanently onto the curved surface of the component 2 by a suitable device or a suitable compression die.

The topology or the curvature of the surface of the component 2 is also transferred to the circuit or the circuit carrier 4 of the power module 1 due to the contact pressure. The circuit carrier 4 may be of a ceramic or organic nature. The die 5.1 for exerting contact pressure on the power semiconductor components 3 may be configured in different variants and press directly or indirectly (e.g., with the aid of a pressure compensation material) onto the power semiconductor components 3 or onto parts of the circuit carrier.

The die 5.1 may be integrated into a casing 5 or configured as an independent component. In addition, the die 5.1 may also be used for making electrical contact with the circuit or as an additional way of heat dissipation from the top side. In one case, application of the necessary contact pressure force may be provided by screws 6 (see FIG. 1), which exert contact pressure on the dies 5.1.

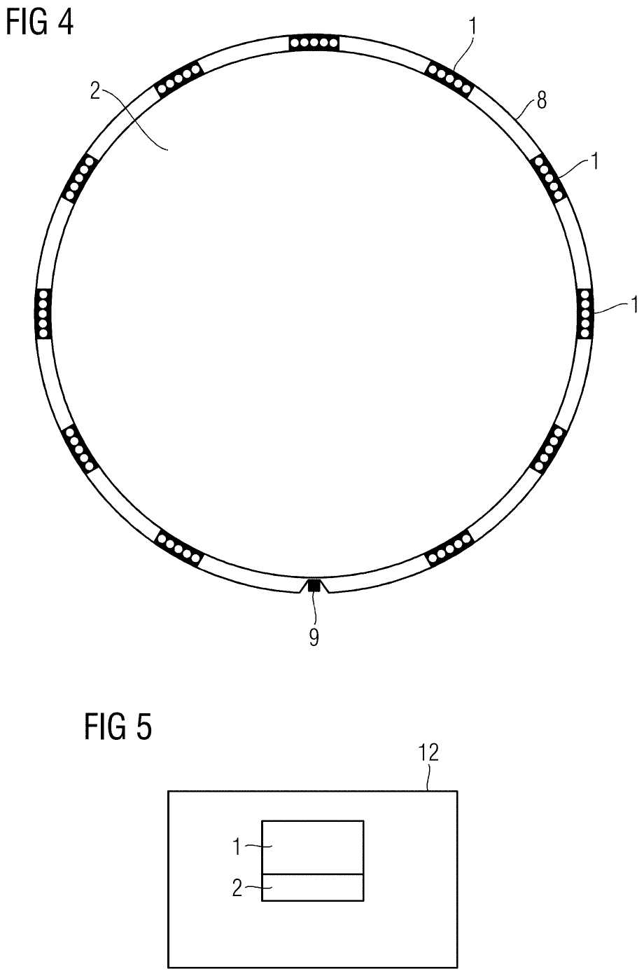

Other solutions are also possible, e.g. pressing down on the power module 1 by a tensioning ring or a tensioning shroud (e.g., shroud loop 7, see FIG. 2) as well as by levers or clamps 8 (see FIG. 3). The use of a shroud loop 7 offers the possibility of arranging a large number of power modules 1 around a cylindrical component 2 (e.g., turbine/propeller casing, motor, cooling pipe, etc.) in a simple manner (see FIG. 4). The ends of the shroud loop 7 are fixed in an anchor point 9 on the component 2. Instead of the shroud loop 7, a shrink-fit tube may be used.

An additional contact force may be generated by a suitable construction of the casing 5 and by utilizing the thermal expansion of the materials used. As a result of the expansion, the power modules 1 are increasingly pressed against the component 2 during the heating operation. The intermediate space between the circuit carrier 4 and the component 2 may be filled with a first thermally conductive material 10 (e.g., thermally conductive paste, thermally conductive pad, thermal oil, graphite pad, etc.) with good thermal conductivity. The intermediate spaces in the casing 5 may be filled with a second thermally conductive material.

FIG. 5 shows a block diagram of a power converter 12, in particular a converter, with a power module 1 attached to a cooler 10 in line with the illustrations of FIG. 1 to FIG. 4.

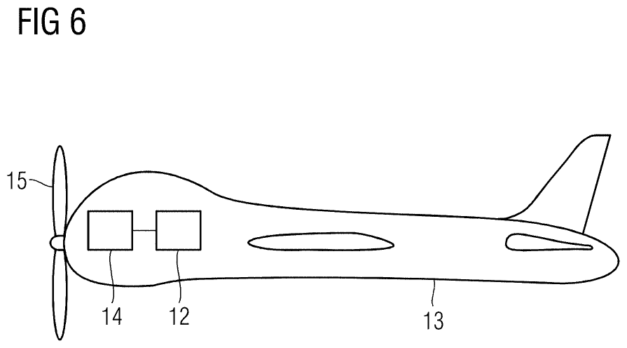

FIG. 6 shows an electric or hybrid-electric aircraft 14, in particular an airplane, including a power converter 12 according to FIG. 5 which supplies an electric motor 15 with electrical energy. The electric motor 15 drives a propeller 16. Both are part of an electrical thrust-generating unit.

Although the disclosure has been described and illustrated more specifically in detail by the exemplary embodiments, the disclosure is not restricted by the disclosed examples and other variations may be derived therefrom by a person skilled in the art without departing from the scope of protection of the disclosure.

It is to be understood that the elements and features recited in the appended claims may be combined in different ways to produce new claims that likewise fall within the scope of the present disclosure. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification,

### LIST OF REFERENCE SIGNS

1 Power module
2 Component (in particular heat sink)
3 Power semiconductor component
4 Circuit carrier
5 Casing
5.1 Die
6 Screw
7 Shroud loop
8 Clamp
9 Anchor point
10 First thermally conductive material
11 Second thermally conductive material
12 Power converter
13 Aircraft
14 Electric motor
15 Propeller

1. An arrangement comprising:
a power module having power semiconductor components; and
a component having a curved surface,
wherein the power module is arranged on the curved surface of the component, and
wherein the power module is releasably connected to the component in a non-positive manner.

2. The arrangement of claim 1, wherein the component is a heat sink.

3. The arrangement of claim 1, wherein the power module has a casing with internal dies, and
wherein the internal dies are configured to press onto the power semiconductor components or a circuit carrier of the power module in direction of the curved surface of the component.

4. The arrangement of claim 3, wherein the power semiconductor components are arranged on the circuit carrier.

5. The arrangement of claim 3, wherein the casing is fixed on the component in a non-positive manner by screws.

6. The arrangement of claim 3, wherein the casing is fixed on the component in a non-positive manner using a shroud loop fixed by screws.

7. The arrangement of claim 3, wherein the casing is fixed on the component in a non-positive manner using clamps.

8. The arrangement of claim 2, wherein a plurality of power modules with casings are fixed on the component in a non-positive manner with aid of a single shroud loop or a shrink-fit tube.

9. The arrangement of claim 8, wherein the component is cylindrical and the shroud loop wraps around the component, and
wherein two ends of the shroud loop are fixed in an anchor point on the component.

10. The arrangement of claim 3, wherein an elastic first thermally conductive material is arranged between the component and the power module.

11. The arrangement of claim 10, wherein the casing is filled with an elastic second thermally conductive material.

12. A power converter comprising:
an arrangement having:
a power module comprising power semiconductor components; and
a component having a curved surface,
wherein the power module is arranged on the curved surface of the component, and
wherein the power module is releasably connected to the component in a non-positive manner.

13. A vehicle comprising:
a power converter for an electric or hybrid-electric drive, wherein the power converter has an arrangement comprising:
a power module comprising power semiconductor components; and
a component having a curved surface,
wherein the power module is arranged on the curved surface of the component, and
wherein the power module is releasably connected to the component in a non-positive manner.

14. The vehicle of claim 13, wherein the vehicle is an aircraft.

15. The vehicle of claim 14, further comprising:
an electric motor configured to be supplied with electrical energy by the power converter; and
a propeller configured to be set in rotation by the electric motor.

16. The arrangement of claim 1, wherein an elastic first thermally conductive material is arranged between the component and the power module.

17. The arrangement of claim 1, wherein the power module has a casing filled with an elastic thermally conductive material.

18. The arrangement of claim 2, wherein the power module has a casing with internal dies, and
wherein the internal dies are configured to press onto the power semiconductor components or a circuit carrier of the power module in direction of the curved surface of the component.

19. The arrangement of claim 18, wherein the casing is fixed on the component in a non-positive manner by screws, a shroud loop fixed by screws, or clamps.
